(19) United States
(12) Patent Application Publication
(10) Pub. No.: US 2009/0152726 A1
(43) Pub. Date: Jun. 18, 2009

(54) METAL LINE OF SEMICONDUCTOR DEVICE AND METHOD FOR FABRICATING THE SAME

(76) Inventor: Kwang-Seon Choi, Yongin-si (KR)

Correspondence Address: SHERR & VAUGHN, PLLC, 620 HERNDON PARKWAY, SUITE 200, HERNDON, VA, 20170, US

(21) Appl. No.: 12/330,622

(22) Filed: Dec. 9, 2008

(30) Foreign Application Priority Data
Dec. 17, 2007 (KR) 10-2007-0131949

(51) Int. Cl. H01L 21/469; H01L 23/48

(52) U.S. Cl. 257/751; 257/764; 438/632; 257/E23.01; 257/E21.487

(57) ABSTRACT

A metal line includes a lower metal line pattern having a first width formed over the dielectric pattern and an upper metal line pattern formed over and contacting the lower metal line pattern such that the upper metal line pattern has a second width less than the first width.

The present application claims priority under 35 U.S.C. § 119 to Korean Patent Application No. 10-2007-0131949 (filed in Dec. 17, 2007), which is hereby incorporated by reference in its entirety.

### BACKGROUND

A metal line connects transistors to each other, supplies power, and transmits signals in an integrated circuit (IC). As a design rule is reduced due to high integration of semiconductor devices, an aspect ratio of the metal line has been increased, i.e., a transverse length or width of the metal line is reduced and a longitudinal length or thickness of the metal line is increased. In order to develop such a semiconductor device, defects of the semiconductor device must be minimized when metal line layers are formed.

### SUMMARY

Embodiments relate to a semiconductor device that may include at least one of the following: a semiconductor substrate including an inter-layer dielectric layer having a device therein, a first insulating layer including a first metal line formed on and/or over the inter-layer dielectric layer, and a second insulating layer including a second metal line formed on and/or over the first insulating layer and contacting the first metal line.

Embodiments relate to a device that may include at least one of the following: a semiconductor substrate; an inter-layer dielectric layer including a device formed over the semiconductor substrate; a first insulating layer including a first metal line formed over the inter-layer dielectric layer; and a second insulating layer including a second metal line formed over the first insulating layer including the first metal line such that the second metal line contacts the first metal line and the second metal line has a width less than the width of the first metal line.

Embodiments relate to a method for fabricating a metal line of a semiconductor device that may include at least one of the following: providing a semiconductor substrate including an inter-layer dielectric layer having a device therein, forming a first insulating layer including a first metal line on and/or over the inter-layer dielectric layer, and forming the metal line including the first and second metal lines by forming a second insulating layer including a second metal line on and/or over the first insulating layer and contacting the first metal line.

Embodiments relate to a method that may include at least one of the following: forming an inter-layer dielectric layer having a device formed therein over a semiconductor substrate; and then forming a first insulating layer including a first metal line portion over the inter-layer dielectric layer; and then forming a metal line including by forming a second insulating layer including a second metal line portion over the first insulating layer including the first metal line portion, whereby the metal line includes the first metal line portion and the second metal line portion and the second metal line portion is formed over and contacts the first metal line portion.

Embodiments relate to a method that may include at least one of the following: forming a dielectric layer having a contact formed therein over a semiconductor substrate; and then forming a lower metal line pattern having a first width over the dielectric pattern; and then forming a metal line over the dielectric layer by forming an upper metal line pattern over and contacting the lower metal line pattern such that the upper metal line pattern has a second width less than the first width.

### DRAWINGS

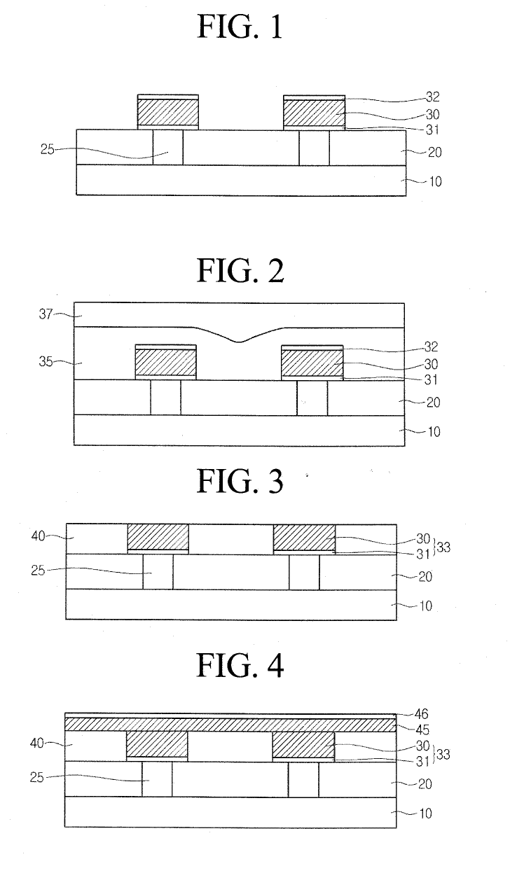

Example FIGS. 1 to 7 illustrate a metal line and a method for fabricating a metal line in accordance with embodiments.

### DESCRIPTION

As shown in example FIG. 1, interlayer dielectric layer 20 is formed on and/or over semiconductor substrate 10. Interlayer dielectric layer 20 may include including a device such as a transistor and contact 25 connected to the device. The contact 25 may include tungsten (W). First diffusion barrier layer pattern 31, first metal layer pattern 30, and second diffusion barrier layer pattern 32 are formed on and/or over inter-layer dielectric layer 20 including contact 25. First diffusion barrier layer pattern 31, first metal layer pattern 30 and second diffusion barrier layer pattern 32 may be formed after forming and patterning a first diffusion barrier layer, a first metal layer, and a second diffusion barrier layer on and/or over inter-layer dielectric layer 20. The first metal layer may include aluminum (Al), and the first and second diffusion layers may include a Ti/TiN stack layer.

As shown in example FIG. 2, first and second insulating layers 35 and 37 are then formed on and/or over inter-layer dielectric layer 20 including first diffusion layer pattern 31, first metal layer pattern 30 and second diffusion layer pattern 32. First insulating layer 35 may include a high density plasma (HDP) layer and second insulating layer 37 may include an undoped silicate glass (USG) layer.

As shown in example FIG. 3, a first planarization process is formed with respect to first and second insulating layers 35 and 37, thereby forming third insulating layer 40 including first metal line 33 having first diffusion barrier layer pattern 31 and first metal layer pattern 30. The first planarization process can be performed until second diffusion barrier layer pattern 32 is removed, such that first metal layer pattern 30 can be exposed. Accordingly, third insulating layer 40 including first metal line 33 having first diffusion barrier layer pattern 31 and first metal layer pattern 30 is formed.

As shown in FIG. 4, second metal layer 45 and third diffusion layer 46 are then formed on and/or over third insulating layer 40 including first metal line 33. Second metal layer 45 may include aluminum (Al) and third diffusion layer 46 may include a Ti/TiN stack layer. Second metal layer 45 may have a thickness which is suitable for resistance required in a device and based on first metal layer pattern 30.

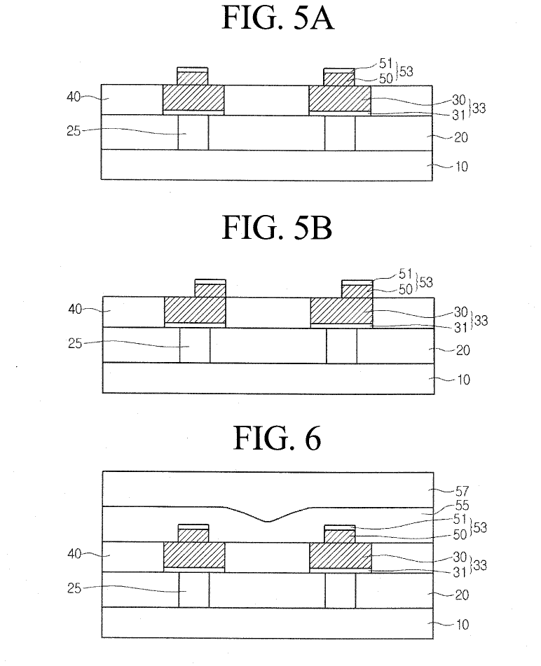

As shown in FIG. 5A, second metal layer 45 and third diffusion barrier layer 46 are patterned, thereby forming second metal line 53 including second metal layer pattern 50 and third diffusion layer pattern 51 on and/or over first metal layer pattern 30. Second metal layer pattern 50 and third diffusion layer pattern 51 may be formed by performing a photo-lithography process with respect to second metal layer 45 and third diffusion barrier layer 46. The width of second metal line 53 including second metal layer pattern 50 and third diffusion barrier layer pattern 51 may be less than the width of first metal line 33. This is necessary for preventing misalignment between first and the second metal lines 33 and 53. The width of second metal line 53 may be reduced by taking the misalignment occurring in the photo-lithography process into consideration. Even if second metal line 53 formed on and/or over first metal line 33 is misaligned, second metal line 53 can be repositioned on and/or over first metal line 33 as shown in example FIG. 5B.

As shown in example FIG. 6, fourth insulating layer 55 and fifth insulating layer 57 are then formed on and/or over third insulating layer 40 including second metal line 53. Fourth insulating layer 55 may include a high density plasma (HDP) layer and fifth insulating layer 57 may include an undoped silicate glass (USG) layer.

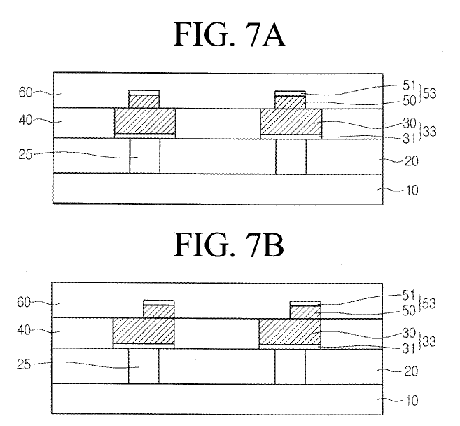

As shown in example FIG. 7A, a second planarization process is performed with respect to fourth insulating layer 55 and fifth insulating layer 57, thereby forming sixth insulating layer 60 including second metal line 53. Accordingly, the metal line in accordance with embodiments includes semiconductor substrate 10 formed with inter-layer dielectric layer 20 having a device formed therein; first insulating layer 40 including first metal line 33 formed on and/or over inter-layer dielectric layer 20, and sixth insulating layer 60 including second metal line 53 formed on and/or over first insulating layer 40 including first metal line 33. Second metal line 53 is formed on and physically contacts first metal line 33. First metal line 33 includes a Ti/TiN/Al stack layer, and second metal line 53 includes an Al/Ti/TiN stack layer, so that the aluminum (Al) of first and second metal lines 33 and 35 contact each other. Second metal line 53 has a smaller width than that of first metal line 33.

As shown in example FIG. 7B, even if second metal line 53 formed on and/or over first metal line 33 is misaligned with respect to first metal line 33, second metal line 53 may be repositioned on and/or over first metal line 33.

In accordance with embodiments, a metal line and a method for fabricating the same, the metal line includes the first and second metal lines formed so that the width of the metal line can be reduced. In addition, the metal line includes first and second metal lines so that the metal line may have a volume identical to that of a related art metal line. Accordingly, low resistance required in a device can be realized. In addition, the width of the second metal line formed on and/or over the first metal line is less than that of the first metal line such that a margin is ensured when the second metal line is formed. Accordingly, misalignment does not occur between the first and second metal lines. Accordingly, a process margin can be ensured, so that the production of a semiconductor device can be smoothly achieved. In addition, even if a semiconductor device may be small-sized, the metal line can be sufficiently formed only by using existing equipment.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A device comprising:
a semiconductor substrate;
an inter-layer dielectric layer including a device formed over the semiconductor substrate;
a first insulating layer including a first metal line formed over the inter-layer dielectric layer; and
a second insulating layer including a second metal line formed over the first insulating layer including the first metal line such that the second metal line contacts the first metal line,
wherein the second metal line has a width less than the width of the first metal line.

2. The device of claim 1, wherein the first metal line and the second metal line are each formed having a multi-layered structure.

3. The device of claim 2, wherein the first metal line comprises a first diffusion barrier layer pattern and a first metal layer pattern and the second metal line comprises a second diffusion barrier layer pattern and a second metal layer pattern.

4. The device of claim 1, wherein the first and second metal layer patterns comprise aluminum (Al) and the first and second diffusion layers comprise a stacked titanium/titanium nitride layer.

5. A method comprising:
forming an inter-layer dielectric layer having a device formed therein over a semiconductor substrate; and then
forming a first insulating layer including a first metal line portion over the inter-layer dielectric layer; and then
forming a metal line including by forming a second insulating layer including a second metal line portion over the first insulating layer including the first metal line portion, wherein the metal line includes the first metal line portion and the second metal line portion and the second metal line portion is formed over and contacts the first metal line portion.

6. The method of claim 5, wherein the second metal line portion has a width less than the width of the first metal line portion.

7. The method of claim 5, wherein the first metal line portion comprises a first diffusion barrier layer pattern and a first metal layer pattern, and the second metal line comprises a second metal layer pattern and a third diffusion layer pattern.

8. The method of claim 7, wherein the first metal layer pattern contacts the second metal layer pattern.

9. The method of claim 7, wherein forming the first insulating layer including the first metal line comprises:
forming the first diffusion barrier layer pattern, the first metal layer pattern, and the second diffusion barrier layer pattern; and then
forming the first insulating layer over the first diffusion barrier layer pattern, the first metal layer pattern, and the second diffusion layer pattern; and then
performing a first planarization process to expose the first metal layer pattern such that the first insulating layer includes the first diffusion barrier layer pattern and the first metal layer pattern.

10. The method of claim 9, wherein the first and second diffusion layers comprise a multi-layer structure including a stacked titanium/titanium nitride layer.

11. The method of claim 5, wherein forming the first insulating layer including the first metal line comprises:
forming a first diffusion barrier layer pattern, a first metal layer pattern, and a second diffusion barrier layer pattern; and then
forming the first insulating layer over the first diffusion barrier layer pattern, the first metal layer pattern, and the second diffusion layer pattern; and then
performing a first planarization process to expose the first metal layer pattern such that the first insulating layer includes the first diffusion barrier layer pattern and the first metal layer pattern.

12. The method of claim 11, wherein forming the metal line comprises:
forming the second metal line portion including a second metal layer pattern and a third diffusion barrier layer pattern; and then
forming the second insulating layer over the second metal layer pattern and the third diffusion barrier layer pattern; and then
performing a second planarization process with respect to the second insulating layer such that the second insulating layer includes the second metal layer pattern and the third diffusion barrier layer pattern.

13. The method of claim 12, wherein the first, second and third diffusion barier layers each comprise a multi-layer structure.

14. The method of claim 13, wherein the multi-layer structure comprises a stacked titanium/titanium nitride layer.

15. The method of claim 7, wherein forming the metal line comprises:
forming the second metal line portion including the second metal layer pattern and the third diffusion barrier layer pattern; and then
forming the second insulating layer over the second metal layer pattern and the third diffusion barrier layer pattern; and then
performing a second planarization process with respect to the second insulating layer such that the second insulating layer includes the second metal layer pattern and the third diffusion barrier layer pattern.

16. The method of claim 15, wherein the third diffusion barrier layer comprise a multi-layer structure including a stacked titanium/titanium nitride layer.

17. A method comprising:
forming a dielectric layer having a contact formed therein over a semiconductor substrate; and then
forming a lower metal line pattern having a first width over the dielectric pattern; and then
forming a metal line over the dielectric layer by forming an upper metal line pattern over and contacting the lower metal line pattern such that the upper metal line pattern has a second width less than the first width.

18. The method of claim 17, wherein forming the lower metal pattern comprises:
simultaneously forming a first diffusion barrier layer pattern, a first metal layer pattern and a second diffusion barrier layer pattern over the dielectric layer; and then
forming a first insulating layer over the dielectric layer including the first diffusion barrier layer pattern, the first metal layer pattern, and the second diffusion layer pattern; and then
exposing the first metal layer pattern by removing the second diffusion barrier layer pattern.

19. The method of claim 18, wherein forming the upper metal line pattern comprises:
forming second metal layer pattern and a third diffusion barrier layer pattern over the lower metal line pattern such that the second metal layer pattern contacts the first metal layer pattern; and then
forming a second insulating layer over the first insulating layer including the second metal layer pattern and the third diffusion barrier layer pattern.

20. The method of claim 18, wherein the first metal layer pattern and the second metal layer pattern are formed of the same material.
